(19) United States
(12) Patent Application Publication
(10) Pub. No.: US 2025/0112604 A1
(43) Pub. Date: Apr. 3, 2025

(54) CURRENT MIRROR CIRCUIT TO COMPENSATE PROCESS VARIATION EFFECTS

(71) Applicant: Apple Inc., Cupertino, CA (US)

(72) Inventors: Sang Hyun Woo, Austin, TX (US); Anandaroop Chakrabarti, San Jose, CA (US)

(21) Appl. No.: 18/735,956

(22) Filed: Jun. 6, 2024

Related U.S. Application Data
(60) Provisional application No. 63/586,119, filed on Sep. 28, 2023.

(51) Int. Cl. H03F 3/45; H03F 1/26

(52) U.S. Cl. CPC H03F 3/45273; H03F 1/26; H03F 2200/294

(57) ABSTRACT

Systems and methods described herein correspond to current mirror circuitry that involves one or more transistors operated in a saturation region and one or more transistors operated in a triode region. By using a combination of transistors operated in the triode region and transistors operated in the saturation region operations, gain of the current mirror circuitry may be adjusted while maintaining permissible amounts of main current generation.

### CROSS-REFERENCE TO RELATED APPLICATIONS

This application claims priority to U.S. Provisional Application No. 63/586,119, filed Sep. 28, 2023, entitled “Current Mirror Circuit to Compensate Process Variation Effects,” which is incorporated by reference herein in its entirety.

### BACKGROUND

The present disclosure relates generally to wireless communication front end circuitry, and more specifically to current mirror circuits that may vary in performance based on process variation.

In an electronic device, a transmitter and a receiver may each be coupled to one or more antennas to enable the electronic device to both transmit and receive wireless signals. Front end circuitry coupled to the transmitter and/or the receiver may adjust one or more signals before or after transmission to the transmitter and/or receiver. Indeed, one or more amplifiers may contribute to the adjustment. These amplifiers may comply with design specifications. As such, it may be desired that a gain associated with one or more amplifiers not deviate from a corresponding design specification.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a device may include a current mirror. The current mirror may include a first transistor having a first threshold voltage. The current mirror may also include a second transistor having a second threshold voltage, the second threshold voltage being less than the first threshold voltage. The current mirror may also include a third transistor having the first threshold voltage. The current mirror may include a current source. The current source may output a reference current to the first transistor, the reference current causing a main current to transmit via the third transistor.

In another embodiment, current mirror circuitry may include a first transistor having a first threshold voltage and a second transistor having a second threshold voltage. The first threshold voltage may correspond to a first gate-source voltage used to operate the first transistor into a saturation region. The second threshold voltage may correspond to a second gate-source voltage used to operate the second transistor into a triode region. The current mirror circuitry may include a third transistor having the first threshold voltage, where the third transistor may have a first gate coupled to a second gate of the first transistor and a third gate of the second transistor.

In yet another embodiment, a method may include operating, via processing circuitry, current mirror circuitry in a first process corner. The method may include receiving, via the processing circuitry, first sensing data associated with a first gain of the current mirror circuitry while operated the first process corner. The method may include operating, via the processing circuitry, the current mirror circuitry in a second process corner. The method may include receiving, via the processing circuitry, second sensing data associated with a second gain of the current mirror circuitry while operated the second process corner. Furthermore, the method may include adjusting, via the processing circuitry, one or more threshold voltages of transistors of the current mirror circuitry based on the first sensing data and the second sensing data.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a circuit diagram of a first example current mirror included within the user equipment of FIG. 1, where the first example current mirror includes triode stacked devices, according to embodiments of the present disclosure;

FIG. 6 is a diagrammatic representation of the first example current mirror of FIG. 5 illustrated adjacent to an associated gain plot and a second example current mirror that does not include triode stacked devices illustrated adjacent to an associated gain plot, according to embodiments of the present disclosure;

FIG. 7 is a diagrammatic representation of the first example current mirror of FIG. 5 illustrating a subset of transistors operated in a triode region and a subset of transistors operated in a saturation region, according to embodiments of the present disclosure;

FIG. 8 is a circuit diagram of a third example current mirror included within the user equipment of FIG. 1, where the third example current mirror includes triode stacked devices and excludes an operational amplifier illustrated in FIG. 5, according to embodiments of the present disclosure;

FIG. 9 is a circuit diagram of a fourth example current mirror included within the user equipment of FIG. 1, where the fourth example current mirror includes triode stacked devices, a resistance, and an additional transistor while excluding the operational amplifier illustrated in FIG. 5, according to embodiments of the present disclosure; and

FIG. 10 is a flow diagram of a method to calibrate and/or test operation of current mirrors that include triode stacked devices, such as the example current mirrors of FIGS. 5, 8, and 9, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to amplifiers and/or circuitry that include current mirror circuit(s). A current mirror circuit may be used to generate, as an output current, a replica of an input current via one or more intercoupled transistors. As sizes of some of the transistors are changed, the current mirror circuit may be used to amplify or adjust a scaling of the output current relative to the input current, which may further expand application of the current mirror circuit. Current mirror circuits may use one or more transistors driven in a saturation region. The relationship (e.g., ratio) between sizes of the transistors in main and reference paths of the current mirror circuit may change an output current variation and a gain. Although current mirror circuits produce relatively constant current outputs, gains associated with current mirrors may vary beyond what is desirable. Indeed, given the amplification uses of the current mirror circuit, improving gain variation of a main circuit through adjustments made to a current mirror circuit may be useful for various reasons. The disclosed current mirror may reduce gain variation of the main circuit that operates based on the disclosed current mirror. In some cases, the main circuit may be a radio frequency (RF) amplifier employing the current mirror circuit, where the RF amplifier may generate an output with decreased gain variation to achieve a more predictive output signal. The main circuit may be any suitable host device. For example, a telephone, a modem, or other suitable RF system may use the main circuit that operates based on the current mirror circuitry described herein. Furthermore, the RF systems may be designed based on industry specifications. For example, an industry specification may specify target gain variation that the RF system is to be designed to meet. Thus, employing these types of current mirror circuits, gain variation may improve of the RF system operating based on the current mirror circuits while satisfying one or more industry specifications.

Embodiments herein provide various systems and methods to adjust gain of current mirror circuitry, enabling associated circuitry that use the current mirror circuitry to have reduced gain variation. Indeed, current mirror circuits described may include multiple transistors in a reference path that have gates interconnected. The multiple transistors may correspond to different sizes relative to sizes of a transistor of the main path. The different sizes may enable respective transistors of the multiple transistors to be operated in either the saturation region or a triode region to selectively tailor the gain of the current mirror to comply with design specifications. The saturation region of a transistor may correspond to a drain-source voltage (Vds) of that transistor being greater than a combination of a gate-source voltage (Vgs) of that transistor with a threshold voltage (Vth) for that transistor (e.g., Vds>(Vgs+Vth)). The triode region of that transistor may correspond to the drain-source voltage (Vds) of that transistor being less than a combination of the gate-source voltage (Vgs) of that transistor with the threshold voltage (Vth) for that transistor (e.g., Vds<(Vgs+Vth)). In this way, the triode region may correspond to a gate-source voltage that is above a threshold voltage of the transistor but low enough to not fully turn the transistor on (e.g., the threshold voltage being less than a second threshold voltage corresponding to the transistor operating in the saturation region). Indeed, the combination of the multiple transistors having different threshold voltages to operate in the saturation region or the triode region may enable gain adjustments.

Other embodiments include a current mirror circuit that includes any number of triode transistors. These systems and methods may be used in current mirror circuits that use an operational amplifier (op amp) in the reference path, that omit an operational amplifier in the reference path, that use a resistance in the reference path, and/or that omit a resistance in the reference path. Indeed, these described systems and methods may be versatile and able to apply to a variety of circuits that use amplifiers.

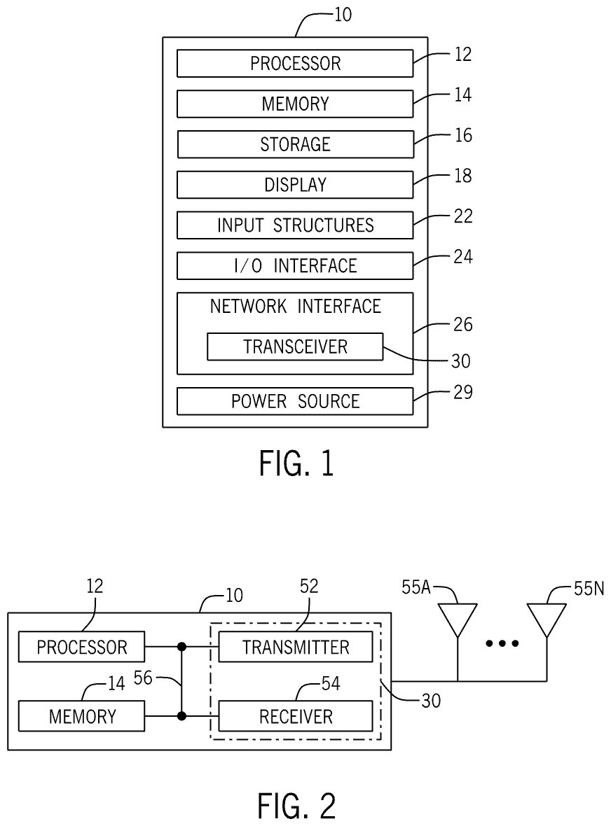

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution® (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The transceiver 30 may include one or more of current mirror circuits, as disclosed herein, that generate, as an output current, a replica of an input current via one or more intercoupled transistors. The current mirror circuit may reduce gain variation of a main circuit (e.g., an RF amplifier of the transceiver 30) that generates an output with decreased gain variation to achieve a more predictive output signal. The current mirror circuit may include multiple transistors in a reference path that have interconnected gates. The multiple transistors may correspond to different sizes relative to sizes of a transistor of the main path. The different sizes may enable respective transistors of the multiple transistors to be operated in either the saturation region or a triode region to selectively tailor the gain of the current mirror to comply with design specifications. The saturation region of a transistor may correspond to a drain-source voltage (Vds) of that transistor being greater than a combination of a gate-source voltage (Vgs) of that transistor with a threshold voltage (Vth) for that transistor (e.g., Vds>(Vgs+Vth)). The triode region of that transistor may correspond to the drain-source voltage (Vds) of that transistor being less than a combination of the gate-source voltage (Vgs) of that transistor with the threshold voltage (Vth) for that transistor (e.g., Vds<(Vgs+Vth)). In this way, the triode region may correspond to a gate-source voltage that is above a threshold voltage of the transistor but low enough to not fully turn the transistor on (e.g., the threshold voltage being less than a second threshold voltage corresponding to the transistor operating in the saturation region). Indeed, the combination of the multiple transistors having different threshold voltages to operate in the saturation region or the triode region may enable gain adjustments. Other embodiments include a current mirror circuit that includes any number of triode transistors. These systems and methods may be used in current mirror circuits that use an operational amplifier (op amp) in the reference path, that omit an operational amplifier in the reference path, that use a resistance in the reference path, and/or that omit a resistance in the reference path. Indeed, these described systems and methods may be versatile and able to apply to a variety of circuits that use amplifiers.

The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

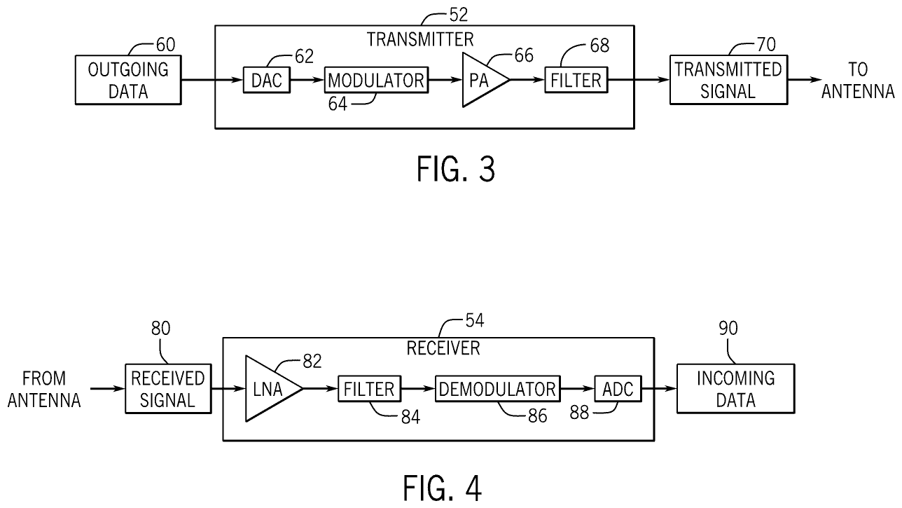

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the received signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

Keeping the foregoing in mind, some electronic devices 10 include amplifier circuitry and/or other circuitry (e.g., including the power amplifier 66 of the transmitter 52 and/or the LNA 82 of the receiver 54) that operate based on current mirror circuitry. This current mirror circuitry may be sometimes referred to as a bias mirror or a bias mirror circuit. Some current mirror circuitry may provide a constant scaling of a reference current (e.g., a bias current) to generate a main current. If the reference current is constant over a process, the main current may also be constant over the process when transistors of the current mirror circuitry are sized substantially equal or within a threshold of variation of each other. Although the main current is constant over ideal operations, sizes of the transistors or characteristics of the current mirror circuitry may be adjusted to change a value of the main current relative to the value of the reference current. In other words, a relationship exists between sizes of the transistors and a value of current generated by the current mirror circuitry. Typical transistors of the current mirror circuitry may each be operated in saturation region to produce the main current. Gain of the current mirror circuitry may vary over various process corners. Process corners may include AG corners defined by current density, voltage threshold, transconductance (gₘ) (e.g., transfer conductance), and gain characteristics of transistors. AG corners may correspond to when current density of a main circuit is relatively low (e.g., less than or equal to 100 microamps divided by micrometers (μA/μm)). In some systems, the gain may vary beyond what is a desired range of gain. However, increasing or decreasing the reference current of a respective process corner may mitigate this gain and reduce the gain below a desired threshold amount. Including one or more triode region stacked devices in current mirror circuitry may enable adaptive control of the reference current in the various process corners. Systems and methods described herein may reduce current consumption of a bias mirror path of the current mirror with a good mismatch. Furthermore, gain may be adjusted based on increasing and/or decreasing a current of the current mirror circuitry based on process corners specific to a system or circuit that operates based on the main current generated by the current mirror circuitry.

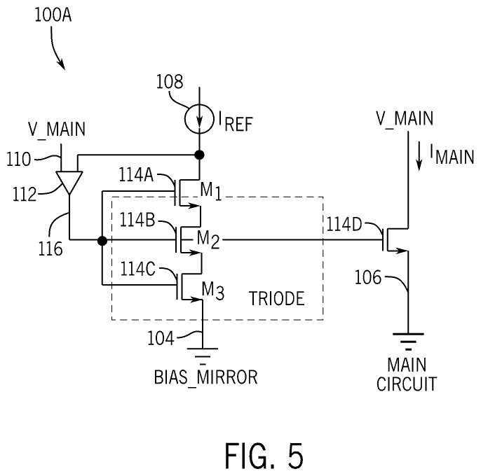

To elaborate, FIG. 5 is a circuit diagram of a first example current mirror, triode region-based current mirror circuitry 100A that may be included within the electronic device 10, where the current mirror circuitry 100A includes triode stacked devices 102, according to embodiments of the present disclosure. The current mirror circuitry 100A includes a bias mirror path 104 and a main circuit path 106.

The bias mirror path 104 receives a reference current (Iref) from a current source 108 and a main or supply voltage (V_Main) via a voltage supply path 110. The main voltage may be received at an operational amplifier 112. In this example, the operational amplifier 112 is coupled to gates of transistors 114 (transistor 114A, transistor 114B, transistor 114C, transistor 114D). The operational amplifier 112 may receive a main voltage (V_Main) via the voltage supply path 110 and provide a voltage output to the gate of the transistors 114 via path 116.

The main circuit path 106 is coupled to the operational amplifier 112 via the transistor 114D. The main circuit path 106 may receive the same main voltage (V_Main) via the voltage supply path 110, and thus may share a node with the operational amplifier 112.

The transistors 114 may have a same width (W) and length (L) or the width and length may vary. In FIG. 5, the transistors 114A-114C have a same width and length different from the width and length of the transistor 114D. The width and length of a channel of a transistor determine electrical characteristics of the transistor, such as a current-carrying capacity, a resistance, a switching speed, and/or a power consumption, or the like. An aspect ratio (W/L) of the respective transistors 114 may indicate a relationship between width and length of the transistor. A higher aspect ratio may correspond to a higher current-carrying capacity and better performance. This improved performance may be balanced relative to increased footprints that may accompany relatively higher aspect ratios when selecting a device size for one or more transistors 114. With this in mind, the device size of the transistors 114A, 114B, and/or 114C may be different, which may correspond to non-equal aspect ratios among the transistors 114A, 114B, and/or 114C.

In the current mirror circuitry 100A, the transistor 114A is coupled to the operational amplifier 112 between its gate and drain, which may cause the transistor 114A to operate in its saturation region based on and/or in response to the reference current. The transistors 114B and 114C are coupled to the gate of the transistor 114A, which may cause the transistors 114B and 114C to operate in the triode region. It is noted that any number of transistors 114 may be included and operate in the triode region. By adding additional transistors 114 that operate in the triode region, further adaptive control of the main current transmitted via the main circuit path 106 may be performed. By operating some of the transistors 114 in the triode region as opposed to the saturation region while operating the other of the transistors 114 in the saturation region, current may be selectively increased (e.g., by the processor 12) at different process corners. Process corners may include corners defined by current density, voltage threshold, transconductance (gₘ) (e.g., transfer conductance), and gain characteristics of transistors. For example, an AG corner may correspond to when current density of a main circuit is relatively low (e.g., less than or equal to 100 microamps divided by micrometers (μA/μm)). While at the AG corner, slow-slow AG (SSAG) process corner may provide transistors a higher voltage threshold (Vth) and higher transconductance (gₘ) and fast-fast AG (FFAG) process corner may provide transistors a lower voltage threshold (Vth) and lower transconductance (gₘ). For example, operating the transistors 114A and 114D in the saturation region and operating the transistors 114B and 114C in the triode region, may increase currents in the FFAG process corner and may decrease currents in the SSAG process corner. It is noted that a transistor may be operated (e.g., by the processor 12) in the triode region based on a gate voltage received by that transistor and its threshold voltage, where a voltage greater than the threshold voltage operates the transistor in its saturation region. Applying voltages to a transistor may operate that transistor in its saturation region or its triode region, and thus a voltage range that corresponds to a triode region of that transistor may vary based on the material used to form that transistor, a width and/or length of that transistor, electrical characteristics of that transistor, another physical characteristic of that transistor, or the like. Selectively increasing current in some of the process and decreasing current in other parts of the process may adjust gain of the main circuit path 106.

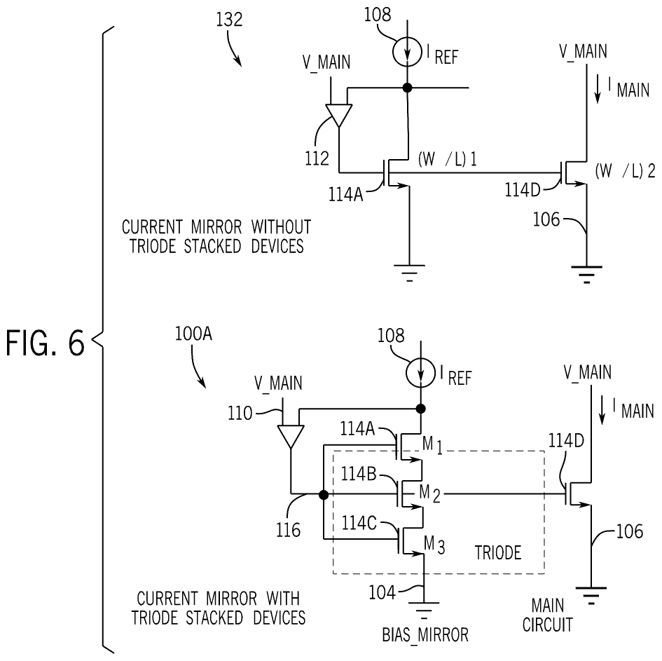

To describe further various example corners and a possible effect of the current mirror circuitry 100A of FIG. 5 on gain variation across the corners, FIG. 6 is a diagrammatic representation of the first example current mirror, triode region-based current mirror circuitry 100A, illustrated adjacent to a second example current mirror, current mirror circuitry 132 that does not include the triode stacked devices 102 of FIG. 5, according to embodiments of the present disclosure. In both current mirror circuitries 100A and 132, the destination block of the main current (Imain) from the main circuit paths 106 may be considered downstream circuitry (e.g., downstream device, main device). The downstream circuitry (not illustrated) may include any suitable circuitry, processing circuitry, sensing circuitry, or the like, and may include amplifiers or other radio frequency (RF) front end (FE) circuitries, or the like, such as those described relative to FIGS. 1-4.

Describing further the current mirror circuitry 100A and 132, the current mirror circuitry 132 may provide X times of the reference current as the main current (e.g., Imain=X*Iref). Over the different process corners, these currents may be substantially constant or negligibly variable. For example, the main and reference currents generated in the SSAG process corner may be substantially equal to the main and reference currents generated in the FFAG process corner. X may be defined according to Equation 1 below.

$$X = \frac{{( W / L )}_{2}}{{( W / L )}_{1}} \qquad [ 1 ]$$

In Equation 1, “W” may refer to a width of a channel of a corresponding transistor, “L” is a length of the channel of that transistor, “W/L” may refer to the aspect ratio of the channel of that transistor, “(W/L)₁” may refer to the aspect ratio of the transistor 114A, and “(W/L)₂” may refer to the aspect ratio of the transistor 114D. Even with a constant main current provided over the process corners, the FFAG corner shows relatively lower gain and the SSAG corner shows relatively higher gain. Indeed, the gain may change between the different process corners since the transconductance (gₘ) changes between the different process corners.

To elaborate, the current mirror circuitry 132 does not include the transistors 114B and 114C. By excluding the transistors 114B and 114C, the current mirror circuitry 132 may experience greater gain variation due to material characteristics of the transistors 114 between the different process corners. Conversely, by including transistors 114B and 114C, the current mirror circuitry 100A may experience reduced gain variation between process corners.

To elaborate, while the current mirror circuitry 132 is in the SSAG process corner, the transconductance (gₘ) of the transistors 114 may be relatively high resulting in a high gain. While the current mirror circuitry 132 is in the FFAG process corner, the transconductance (gₘ) of the transistors 114 may be relatively lower resulting in a low gain. If the reference current (Iref) is maintained over the process, the main current (Imain) may be constant between SSAG process corner and FFAG process corner (e.g., where variation in the main current (Imain) is negligible or less than a threshold).

In comparison to current mirror circuitry 132, the current mirror circuitry 100A includes the transistors 114B and 114C. Including additional transistors may affect a value of the main current (Imain) generated. For the SSAG process corner, although the transconductance (gₘ) of the transistors 114 may still be relatively high, the main current (Imain) generated by the current mirror circuitry 100A may be lower than the main current (Imain) produced by the current mirror circuitry 132 due to the inclusion of the transistors 114B and 114C. The decreased main current (Imain) decreases gain (e.g., changes from high gain via current mirror circuitry 132 to low gain via current mirror circuitry 100A). For the FFAG process corner, although the transconductance (gₘ) of the transistors 114 may still be relatively low, the main current (Imain) generated by the current mirror circuitry 100A may be greater than the main current (Imain) produced by the current mirror circuitry 132 due to the inclusion of the transistors 114B and 114C. The increased main current (Imain) increases gain (e.g., change from low gain via current mirror circuitry 132 to high gain via current mirror circuitry 100A). Thus, gain variation tightens over the process corners.

To elaborate further on the operation of the triode region-based current mirror circuitry 100A of FIGS. 5 and 6, FIG. 7 is a diagrammatic representation of the first example current mirror, triode region-based current mirror circuitry 100A, illustrating the transistors 114B and 114C operated in a triode region and the transistors 114A and 114D operated in a saturation region, according to embodiments of the present disclosure.

Equation 2 may correspond to a relationship between the reference current of the current source and a value of the threshold voltage (Vth) used for the transistors 114B and 114C (e.g., triode stacked devices 102).

$${I}_{REF} = K * ( 2 ( {V}_{GS} - {V}_{TH} ) {V}_{DS} - {{V}_{DS}}^{2} ) \qquad [ 2 ]$$

In Equation 2, “I_{REF}” may refer to a reference current from the current source 108 corresponding to the drain current of that transistor, “K” may refer to a constant indicating a relationship between the voltages and the reference current, which may correspond to a resistance value related to a product of mobility, oxide capacitance, and a ratio between width and length of that transistor (e.g., W/L), as further described relative to Equation 5, “V_{GS}” may refer to a gate-source voltage of both transistors 114B, 114C operated in the triode region, “V_{TH}” may refer to a threshold voltage of both transistors 114B, 114C operated in the triode region, and “V_{DS}” may refer to a drain-source voltage of both transistors 114B, 114C operated in the triode region.

Equation 3 may correspond to a relationship between the reference current and a value of the threshold voltage (Vth) of the transistor 114A. The relationship corresponding to Equation 3 may be used to determine a value of the reference current to operate the transistor 114A in its saturation region.

$${I}_{REF} = K * {( {V}_{GS} - {V}_{TH} )}^{2} \qquad [ 3 ]$$

In Equation 3, “I_{REF}” may refer to a reference current from the current source 108 corresponding to the saturation region, “K” may refer to a constant indicating a relationship between the voltages and the reference current, which may correspond to a resistance value, “V_{GS}” may refer to a gate-source voltage of the transistor 114A operated in the saturation region, and “V_{TH}” may correspond to a threshold voltage of the transistor 114A operated in the saturation region.

Equation 4 may correspond to a relationship between the main current of the main circuit path 106 and a value of the threshold voltage (Vth) of the transistor 114D. The relationship corresponding to Equation 4 may be used to determine a value of the main current to operate the transistor 114D in its saturation region.

$${I}_{main} = K * {( {V}_{GS} - {V}_{TH} )}^{2} \qquad [ 4 ]$$

In Equation 4, “Iₘₐᵢₙ” may refer to a main current of the main circuit path 106 corresponding to the saturation region, “K” may refer to a constant indicating a relationship between the voltages and the main current, which may correspond to a resistance value, “V_{GS}” may refer to a gate-source voltage of the transistor 114D operated in the saturation region, and “V_{TH}” may correspond to a threshold voltage of the transistor 114D operated in the saturation region.

The “K” referred to in relationships represented via Equations 2-4 may correspond to a value determined based on relationship of Equation 5.

$$K = \frac{μ * C * W}{L} \qquad [ 5 ]$$

In Equation 5, “μ” may refer to a charge mobility of that transistor, “C” may refer to an oxide capacitance value of that transistor, “W” may refer to a channel width of that transistor, and “L” may refer to a channel length of that transistor.

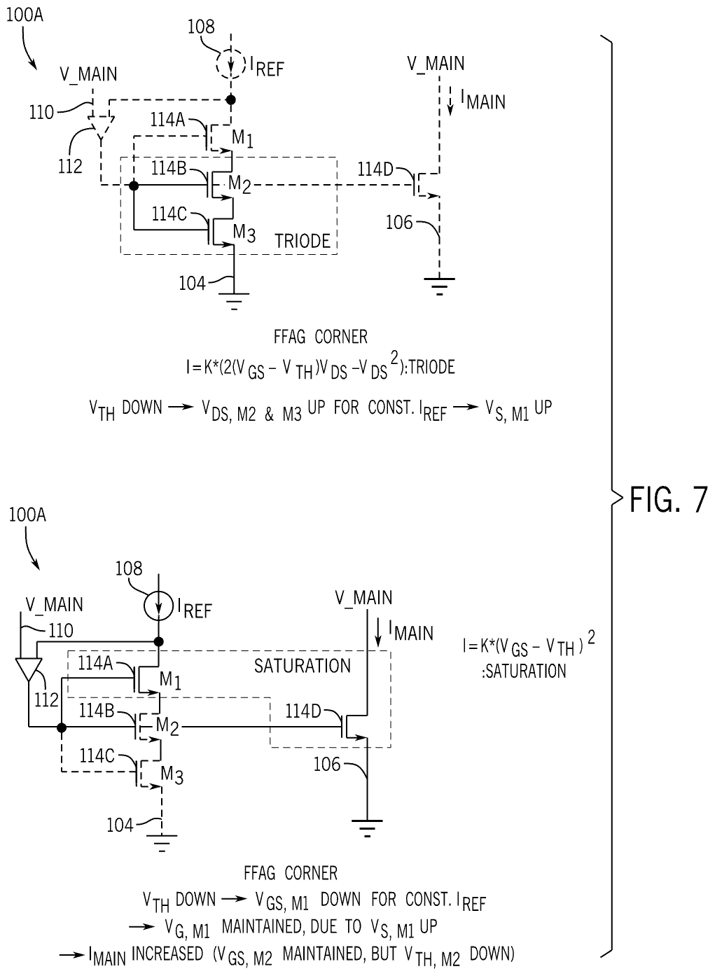

FIG. 7 may help illustrate that main current (Imain) can be adaptively controlled over process corners. For example, in the FFAG corner, the respective threshold voltages (Vth) of the transistors 114 may be relatively lower compared to Typical process corner. With the lower threshold voltages (Vth), the drain source voltages (Vds) of the transistors 114B and 114C may be relatively higher (compared to Typical corner) to maintain the reference current (Iref) from the current source 108. This implies that the source voltage (Vs) of transistor 114A may be relatively higher compared to Typical corner. As a result, the gate voltage of transistor 114A cannot reduce proportionately with Vth reduction in FFAG corner to maintain the reference current (Iref). In turn, the gate voltage (Vg) of transistor 114D may not reduce proportionately with threshold voltage (Vth) reductions in FFAG corner, causing the main current (Imain) to be higher than X*Iref as described above relative to the current mirror circuitry 132. Consequently, the gain relative to current mirror circuitry 132, and hence the gain of transistor 114D, increases while in the FFAG process corner relative to that of the current mirror circuitry 132. This helps reduce deviation from Typical corner gain.

Furthermore, in the SSAG process corner, the respective threshold voltages (Vth) of the transistors 114 may be relatively greater than those of FFAG process corner. When the threshold voltages (Vth) are relatively higher (compared to Typical process corner), the drain source voltages (Vds) of the transistors 114B and 114C may be relatively lower to maintain the reference current (Iref). This implies that the source voltage (Vs) of transistor 114A may be relatively lower compared to Typical corner. As a result, the gate voltage of transistor 114A cannot increase proportionately with Vth increase in SSAG corner to maintain the reference current (Iref). In turn, the gate voltage (Vg) of transistor 114D may not increase proportionately with threshold voltage (Vth) reductions in SSAG corner, causing the main current (Imain) to be lower than X*Iref as described above relative to the current mirror circuitry 132. Consequently, the gain relative to current mirror circuitry 132, and hence the gain of transistor 114D decreases while in the SSAG process corner relative to that of the current mirror circuitry 132. Again, this helps reduce deviation from Typical corner gain. Based on these characteristics of the current mirror circuitry 100A, the gain variation over process may be reduced.

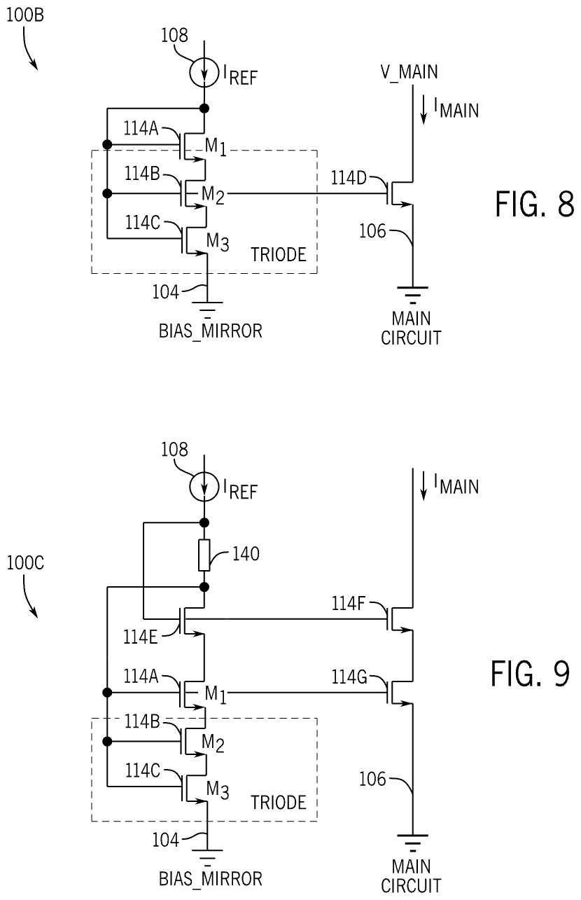

With the foregoing in mind, FIG. 8 and FIG. 9 present additional example current mirrors. These additional example circuitries may operate similar to the current mirror of FIGS. 5 and 7 to achieve similar benefits as described above, and may serve to illustrate the operational flexibility of the systems and methods described herein. In both examples, a combination of transistors that respectively have one or more different threshold voltages (Vth), which enable operation in the saturation region (e.g., first Vth) or the triode region (e.g., second Vth less than the first Vth), may adjust the gain of the current mirror circuitry 100.

Indeed, FIG. 8 is a circuit diagram of a third example current mirror, triode region-based current mirror circuitry 100B that may be included within the electronic device 10, that includes triode stacked devices 102 and excludes an operational amplifier (e.g., operational amplifier 112 of FIG. 5), according to embodiments of the present disclosure. The current mirror circuitry 100B illustrates that these systems and methods described herein may adjust gain without the inclusion of the operational amplifier 112.

The current source 108 may be coupled to the drain of the transistor 114A and the gate of the transistor 114A. The source of the transistor 114A may be coupled to the drain of the transistor 114B. The gate of the transistor 114A may be coupled to the gate of the transistor 114B, the gate of the transistor 114C, and the gate of the transistor 114D. The source of the transistor 114B may be coupled to the drain of the transistor 114C. The source of the transistor 114C may be coupled to ground (e.g., a ground path, a grounded coupling, a voltage ground). The transistors 114B and 114C may have a threshold voltage such that when voltage is received based on the reference current, the transistors 114B and 114C operate in the triode region. The transistors 114A and 114D may have a threshold voltage such that when voltage is received based on the reference current, the transistors 114A and 114D operate in the saturation region. Based on the specific designs (e.g., aspect ratio, material characteristics) of the respective transistors, the value of the threshold voltages may differ to cause operation in the triode or saturation region. In other words, transistor 114B and transistor 114C may have different material properties that lead to each transistor using a different threshold voltage to operate in the triode region and/or transistor 114A and transistor 114D may have different material properties that lead to each transistor using a different threshold voltage to operate in the saturation region. It is noted that in some systems, transistor 114B (e.g., M₂) is considered part of the main circuit.

Continuing on to yet another example, FIG. 9 is a circuit diagram of a fourth example current mirror, triode region-based current mirror circuitry 100C that may be included within the electronic device 10, that includes the triode stacked devices 102, a resistance 140, and an additional transistors 114 (e.g., transistor 114E, transistor 114F, transistor 114G) and excludes an operational amplifier (e.g., operational amplifier 112 of FIG. 5), according to embodiments of the present disclosure. The current mirror circuitry 100C illustrates that these systems and methods described herein may adjust gain without the operational amplifier 112.

The current source 108 may be coupled to the resistance 140. The resistance 140 may be any suitably sized resistor, inductance, capacitance, or a combination thereof and/or may represent a system impedance, a path impedance, or a device included in the bias mirror path 104, or any combination thereof. The current mirror circuitry 100C may include additional transistors, transistor 114F and transistor 114G, in the main circuit path 106 and transistor 114E in the bias mirror path 104. The resistance 140 may be coupled to the gate of the transistor 114E, the gate of the transistor 114F, the gate of the transistor 114A, and the gate of the transistor 114G. The gate of the transistor 114G may also be coupled to the gates of the transistor 114A, the transistor 114B, and the transistor 114C. The drain of the transistor 114A may be coupled to the source of the transistor 114E. The drain of the transistor 114B may be coupled to the source of the transistor 114A. The drain of the transistor 114C may be coupled to the source of the transistor 114B and the source of the transistor 114C may be coupled to a ground.

Current mirror circuitry 100A, current mirror circuitry 100B, and current mirror circuitry 100C each include two transistors 114 operated in a triode region based on a threshold voltage of the respective transistors. Although two triode stacked devices 102 are included in this current mirror circuitry 100A, current mirror circuitry 100B, and current mirror circuitry 100C, it should be understood that any number of triode region transistors 114 may be used.

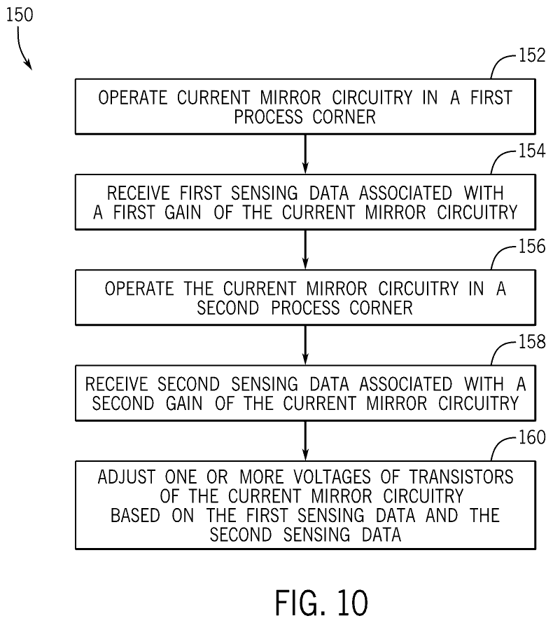

Keeping the foregoing in mind, one or more of the current mirror circuitries 100 may undergo a calibration or testing of the circuitry to confirm whether the transistors 114 are suitably sized and/or have target characteristics to produce a desired gain and/or output current variation. FIG. 10 illustrates example operations that may be performed to calibrate and/or test one or more of the current mirror circuitries 100.

FIG. 10 is a flowchart of a method 150 to calibrate dimensions and/or electrical characteristics of one or more current mirror circuitries 100 to adjust gain and/or output current, according to embodiments of the present disclosure. Any suitable device (e.g., a controller) that may control components of an electronic device 10, such as processor 12 (e.g., on-board processing circuitry) of the electronic device 10 and/or external processing circuitry of another electronic device 10 (e.g., a testing device), may perform the method 150. In some embodiments, the method 150 may be implemented by executing instructions stored in a tangible, non-transitory, computer-readable medium, such as the memory 14 or storage 16, using the processor 12. For example, the method 150 may be performed at least in part by one or more software components, such as an operating system of the electronic device 10, one or more software applications of the electronic device 10, and the like. While the method 150 is described using steps in a specific sequence, it should be understood that the present disclosure contemplates that the described steps may be performed in different sequences than the sequence illustrated, and certain described steps may be skipped or not performed altogether. Furthermore, while the method 150 is described using one of the current mirror circuitries 100 (e.g., as current mirror circuitry 100), it should be understood that these determination, testing, and adjustment operations may be similarly applied to any of the current mirror circuitries 100 and/or other current mirror circuitries not specifically illustrated herein that operate based on one or more triode stacked devices 102.

In process block 152, the processor 12 operates the current mirror circuitry 100 (e.g., device-under-test (DUT)) in a first process corner. The first process corner may include a respective process corner illustrated in FIG. 6. In some systems, the first process corner may include a different combination of operational characteristics (e.g., process, voltage, temperature (PVT)) than that illustrated in FIG. 6. In particular, the processor 12 may send a request to an environmental control system to adjust a temperature or of a testing environment. The processor 12 may send a control signal to trigger a sensing operation to determine a value of an ambient temperature of the testing environment. The processor 12 may adjust voltages, such as V_main to a desired testing value and/or the processor 12 may adjust a process and/or operation that is associated with the current mirror circuitry 100 to test performance in the adjusted process and/or adjusted operation. Adjusting PVT values to change between process corners may cause a change a carrier mobility of one or more of the transistors 114, which may change performance of the current mirror circuitry 100 in the various process corners.

In process block 154, the processor 12 receives first sensing data associated with the current mirror circuitry 100 (e.g., associated with a first gain). The processor 12 may generate a control signal to start a sensing operation while the current mirror circuitry 100 is operated in the first process corner. Thus, the first sensing data received in response to the sensing operation corresponds to the current mirror circuitry 100 being operated in the first process corner. The first sensing data may include an indication of a first gain of the current mirror circuitry 100 and/or an indication of a first output current of the current mirror circuitry 100.

In process block 156, the processor 12 operates the current mirror circuitry 100 in a second process corner. The second process corner may correspond to an at least partially different combination of PVT (e.g., temperature and voltage may be the same but process may be changed). Thus, the processor 12 may repeat sensing operations since performance of the current mirror circuitry 100 may change in response to one or more changes in PVT values.

In process block 158, the processor 12 receives second sensing data associated with the current mirror circuitry 100 (e.g., associated with a second gain). The processor 12 may generate a control signal to perform another sensing operation while the current mirror circuitry 100 is operated in the second process corner. Thus, the second sensing data received in response to the sensing operation corresponds to the current mirror circuitry 100 being operated in the second process corner. The second sensing data may include an indication of a second gain of the current mirror circuitry 100 and/or an indication of a second output current of the current mirror circuitry 100.

In process block 158, the processor 12 adjusts a voltage or other suitable parameter of one or more transistors 114 of the current mirror circuitry 100 based on the first sensing data and the second sensing data. For example, the processor 12 may reduce gate voltage of one or more transistors 114 to adjust a gain to a target gain amount. In some cases, the processor 12 compares more than two sensing data, such as was the case generally described relative to FIG. 6.

In some testing or calibration operations, the processor 12 may determine a reference current to be applied to the current mirror circuitry 100 to perform the method of 150. The processor 12 may adjust the current source 108 to adjust the reference current based on the determination. The processor 12 may reference data stored in memory 14 associating one or more combinations of PVT values to a desired reference current value. In some cases, the processor 12 may adjust the reference current based on a system that includes and/or operates based on the current mirror circuitry 100, such as a type of sub-system of the electronic device 10 includes the current mirror circuitry 100. The type of sub-system may correspond to any variety of sub-systems and/or circuitries described herein, including a power amplifier 66, a radio frequency front end system, other circuitries described in FIGS. 1-4, or the like. Indeed, current mirror circuitry 100 may be suitable for use in a variety of portions of the electronic device 10 where a gain and/or gain variation is desired to be tailored for a particular use.

Technical effects of the present disclosure include reducing gain variation of a main circuit based on current mirror systems and methods described herein. Indeed, current mirror circuitry is described herein that involves one or more transistors operated in a triode region and one or more transistors operated in a saturation region. By doing so, gain variation may be reduced and/or designed for use with the main circuit while maintaining permissible amounts of main current generation (e.g., tailored to the particular system).

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

It is claimed:

1. A device comprising:
a current mirror comprising
a first transistor having a first threshold voltage,
a second transistor having a second threshold voltage, the second threshold voltage being less than the first threshold voltage, and
a third transistor having the first threshold voltage; and
a current source configured to output a reference current to the first transistor, the reference current causing a main current to transmit via the third transistor.

2. The device of claim 1, comprising a downstream circuit configured to couple to the current mirror, wherein the downstream circuit receives a current from the current mirror based on the main current being transmitted via the third transistor.

3. The device of claim 1, wherein the second transistor is configured to operate in a triode region based on the reference current and the second threshold voltage.

4. The device of claim 1, wherein the second transistor is configured to operate in a triode region while the first transistor operates in a saturation region.

5. The device of claim 1, wherein the current source is coupled to a drain of the first transistor, a gate of the first transistor is coupled to a gate of the second transistor, a source of the first transistor is coupled to a drain of the second transistor, and a source of the second transistor is coupled to ground.

6. The device of claim 5, wherein a gate of the third transistor is coupled to the gate of the first transistor and to the gate of the second transistor.

7. The device of claim 1, comprising a fourth transistor having the first threshold voltage.

8. The device of claim 7, wherein the current source is coupled to a drain of the first transistor and to a gate of the first transistor, a gate of the second transistor, a gate of the third transistor, and a gate of the fourth transistor.

9. The device of claim 7, wherein the current source is coupled to a drain of the first transistor and to an operational amplifier, and an output of the operational amplifier is coupled to a gate of the first transistor, a gate of the second transistor, a gate of the third transistor, and a gate of the fourth transistor.

10. Current mirror circuitry comprising:
a first transistor having a first threshold voltage, the first threshold voltage corresponding to a first gate-source voltage used to operate the first transistor into a saturation region;
a second transistor having a second threshold voltage, the second threshold voltage corresponding to a second gate-source voltage used to operate the second transistor into a triode region; and
a third transistor having the first threshold voltage, the third transistor having a first gate being coupled to a second gate of the first transistor and a third gate of the second transistor.

11. The current mirror circuitry of claim 10, wherein the third transistor is configured to provide a main current based on the first transistor receiving a reference current.

12. The current mirror circuitry of claim 11, wherein the second transistor operates in the triode region based on a current from the first transistor causing the second gate-source voltage across the third gate of the second transistor and a source of the second transistor.

13. The current mirror circuitry of claim 10, comprising a fourth transistor having the second threshold voltage.

14. The current mirror circuitry of claim 13, comprising a current source configured to output a reference current, wherein the current source is coupled to a drain of the first transistor, a gate of the first transistor, a gate of the second transistor, a gate of the third transistor, and a gate of the fourth transistor, and wherein the third transistor is configured to transmit a main current based on the reference current received at the gate of the third transistor.

15. The current mirror circuitry of claim 14, comprising an operational amplifier that receives a supply voltage and provides a voltage output to the gate of the first transistor, the gate of the second transistor, the gate of the third transistor, and the gate of the fourth transistor, wherein the third transistor is configured to transmit the main current based on the reference current received at the gate of the third transistor and based on the supply voltage.

16. The current mirror circuitry of claim 10, comprising a resistance, a current source, and a fourth transistor, wherein the current source is coupled to the resistance, the resistance is coupled to a drain of the fourth transistor, a source of the fourth transistor is coupled to a drain of the first transistor, and a source of the first transistor is coupled to a drain of the second transistor.

17. A method comprising:
operating, via processing circuitry, current mirror circuitry in a first process corner;
receiving, via the processing circuitry, first sensing data associated with a first gain of the current mirror circuitry while operated the first process corner;
operating, via the processing circuitry, the current mirror circuitry in a second process corner;
receiving, via the processing circuitry, second sensing data associated with a second gain of the current mirror circuitry while operated the second process corner; and
adjusting, via the processing circuitry, one or more voltages of transistors of the current mirror circuitry based on the first sensing data and the second sensing data.

18. The method of claim 17, comprising:
determining, via the processing circuitry, a current to be applied to the current mirror circuitry in the first process corner based on a system comprising the current mirror circuitry; and
adjusting, via the processing circuitry, a current source based on the current to be applied.

19. The method of claim 18, comprising determining, via the processing circuitry, that the system comprising the current mirror circuitry corresponds to a power amplifier.

20. The method of claim 18, comprising determining, via the processing circuitry, that the system comprising the current mirror circuitry corresponds to a radio frequency front end system.
